(19) United States
(12) Patent Application Publication
(10) Pub. No.: US 2020/0035465 A1
(43) Pub. Date: Jan. 30, 2020

(54) SUBSTRATE PROCESSING APPARATUS AND PLASMA SHEATH HEIGHT CONTROL METHOD

(71) Applicant: TOKYO ELECTRON LIMITED, Tokyo (JP)

(72) Inventor: Kenji Matsumoto, Miyagi (JP)

(73) Assignee: TOKYO ELECTRON LIMITED, Tokyo (JP)

(21) Appl. No.: 16/522,979

(22) Filed: Jul. 26, 2019

(30) Foreign Application Priority Data
Jul. 27, 2018 (JP) 2018-140827

(51) Int. Cl. H01J 37/32; H01L 21/687

(52) U.S. Cl. CPC H01J 37/32642; H01J 37/32724; H01J 2237/334; H01L 21/68742; H01L 21/68764

(57) ABSTRACT

A substrate processing apparatus includes a substrate mounting unit, a support unit, a thickness variable layer, and a control unit. The substrate mounting unit has an upper surface that serves as a mounting surface on which a target substrate to be processed is mounted. The support unit has therein a flow path for a heat transfer medium and is configured to support the substrate mounting unit. The thickness variable layer is disposed between the substrate mounting unit and the support unit, and a thickness of the thickness variable layer changes due to expansion or shrinkage caused by a predetermined process. The control unit is configured to control the thickness of the thickness variable layer by performing the predetermined process.

### CROSS-REFERENCE TO RELATED APPLICATIONS

This application claims priority to Japanese Patent Application No. 2018-140827, filed on Jul. 27, 2018, the entire contents of which are incorporated herein by reference.

### TECHNICAL FIELD

The present disclosure relates to a substrate processing apparatus and a plasma sheath height control method.

### BACKGROUND

Japanese Patent Application Publication No. 2008-244274 discloses a technique for raising a focus ring disposed to surround an outer peripheral portion of a semiconductor wafer in response to a consumption of the focus ring.

### SUMMARY

The present disclosure provides a technique capable of extending a replacement cycle of a focus ring with a simple configuration.

In accordance with an embodiment of the present disclosure, there is provided a substrate processing apparatus, including: a substrate mounting unit having an upper surface that serves as a mounting surface on which a target substrate to be processed is mounted; a support unit having therein a flow path for a heat transfer medium and configured to support the substrate mounting unit; a thickness variable layer disposed between the substrate mounting unit and the support unit and having a thickness that changes due to expansion or shrinkage caused by a predetermined process; and a control unit configured to control the thickness of the thickness variable layer by performing the predetermined process.

### BRIEF DESCRIPTION OF THE DRAWINGS

The objects and features of the present disclosure will become apparent from the following description of embodiments, given in conjunction with the accompanying drawings, in which:

FIG. 1 is a cross-sectional view showing an example of a schematic configuration of a substrate processing apparatus according to a first embodiment;

FIG. 2 is a cross-sectional view schematically showing an example of a main configuration of a mounting table according to the first embodiment;

FIGS. 3A and 3B show examples of shrinkage of a shrinkable material depending on a temperature according to the first embodiment;

FIG. 4 shows an example of changes in a film thickness of a thickness variable layer with a temperature according to the first embodiment;

FIGS. 5A to 5C explain examples of operations and effects of the first embodiment;

FIG. 6 shows a flow of the thickness control of the thickness variable layer according to the first embodiment;

FIG. 7 is a cross-sectional view schematically showing an example of a main configuration of a mounting table according to a second embodiment;

FIG. 8 shows an example of changes in a film thickness of the thickness variable layer with a temperature according to the second embodiment; and

FIGS. 9A to 9C explain examples of operations and effects of the second embodiment.

### DETAILED DESCRIPTION

Hereinafter, embodiments of a substrate processing apparatus and a plasma sheath height control method of the present disclosure will be described in detail with reference to the accompanying drawings. The following embodiments are not intended to limit the substrate processing apparatus and the plasma sheath height control method of the present disclosure.

In a substrate processing apparatus for performing substrate processing such as plasma processing or the like on a target substrate such as a semiconductor wafer (hereinafter, referred to as “wafer”) or the like, a focus ring is disposed to surround an outer peripheral portion of the wafer to improve plasma uniformity. The focus ring is consumed during the plasma processing, and thus is treated as a consumable part and replaceable part.

However, the focus ring is expensive, and the cost of consumables (COC) thereof becomes high as the lifespan or the replacement cycle thereof is shortened. When a wet cleaning of the substrate processing apparatus is performed due to the replacement of the focus ring, a wet cleaning cycle (mean time between wet cleaning (MTBWC)) is shortened, which results in a decrease in the operation rate of the substrate processing apparatus. Therefore, it is considered to extend the replacement cycle of the focus ring with a simple configuration.

### First Embodiment

<Configuration of Apparatus>

First, an example of the substrate processing apparatus will be described. The substrate processing apparatus performs plasma processing on a target substrate to be processed. In the present embodiment, a case where the substrate processing apparatus is a plasma processing apparatus for performing plasma etching on a wafer will be described as an example.

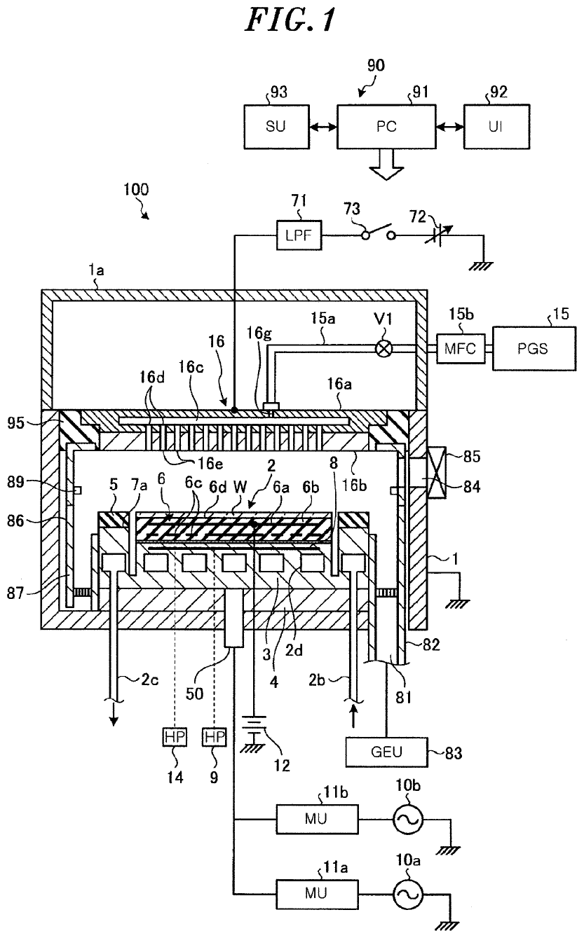

FIG. 1 is a cross-sectional view showing an example of a schematic configuration of a substrate processing apparatus according to a first embodiment. A substrate processing apparatus 100 includes an airtight processing chamber 1 that is electrically grounded. The processing chamber 1 has a cylindrical shape and is made of, e.g., aluminum or the like. The processing chamber 1 defines a processing space where plasma is generated. A mounting table 2 for horizontally supporting a wafer W that is the target substrate is accommodated in the processing chamber 1. In the present embodiment, the mounting table 2 includes a base 3 and an electrostatic chuck 6. In the present embodiment, the electrostatic chuck 6 corresponds to a substrate mounting portion, and the base 3 corresponds to a support portion.

The base 3 has a substantially cylindrical shape and is made of a conductive metal, e.g., aluminum or the like. The base 3 serves as a lower electrode. The base 3 is supported by a support 4 that is an insulator, and the support 4 is installed at a bottom portion of the processing chamber 1. The base 3 is fastened at a bottom side thereof to the support 4 by, e.g., screws. The electrostatic chuck 6 is disposed at a central portion of the mounting table 2 when viewed from the top, and is configured to electrostatically attract and hold the wafer W.

The electrostatic chuck 6 has an electrode 6a and an insulator 6b. The electrode 6a is disposed in the insulator 6b, and a DC power supply 12 is connected to the electrode 6a. The electrostatic chuck 6 electrostatically attracts and holds the wafer W by the Coulomb force generated by applying a DC voltage from the DC power supply 12 to the electrode 6a. The electrostatic chuck 6 is provided with one or more heaters 6c. The heaters 6c are connected to a heater power supply (HP) 14. The heaters 6c extend annularly to surround the center of the mounting table 2. The heaters 6c may include, e.g., heaters for heating a central region, and heaters extending annularly to surround the outer side of the central region. In this case, the heaters 6c may control a temperature of the wafer W in each of the regions divided radially with respect to the center of the wafer W.

An annular focus ring 5 is disposed at an outer side of the electrostatic chuck 6. The focus ring 5 is made of, e.g., single crystalline silicon, and is supported by the base 3.

A power feed rod 50 is connected to the base 3. The power feed rod 50 is connected to a first RF power supply 10a through a first matching unit (MU) 11a and connected to a second RF power supply 10b through a second matching unit (MU) 11b. The first RF power supply 10a supplies a high frequency power for plasma generation, which has a predetermined frequency, to the base 3 of the mounting table 2. The second RF power supply 10b supplies a high frequency power for ion attraction (bias), which has a predetermined frequency lower than that of the first RF power supply 10a, to the base 3 of the mounting table 2.

A flow path 2d for a heat transfer medium is formed in the base 3. The flow path 2d is connected to an inlet line 2b and an outlet line 2c. By circulating a heat transfer medium, e.g., a coolant such as cooling water or the like, in the flow path 2d, a temperature of the mounting table 2 can be controlled to a predetermined temperature. In addition, a gas supply line for supplying a cold heat transfer gas (backside gas) such as helium gas or the like to the backside of the wafer W may be provided to penetrate through the mounting table 2 or the like. The gas supply line is connected to a gas supply source. With this configuration, the wafer W electrostatically attracted and held by the electrostatic chuck 6 on the upper surface of the mounting table 2 can be controlled to a predetermined temperature.

One or more heaters 8 are disposed in the base 3. The heaters 8 are connected to a heater power supply (HP) 9.

A shower head 16 serving as an upper electrode is arranged above the mounting table 2 to be opposite to the mounting table 2 in parallel therewith. The shower head 16 and the mounting table 2 function as a pair of electrodes (the upper electrode and the lower electrode).

The shower head 16 is provided at a ceiling wall portion of the processing chamber 1. The shower head 16 is supported at an upper portion of the processing chamber 1 through an insulating member 95. The shower head 16 includes a main body 16a and a ceiling plate 16b serving as an electrode plate. The main body 16a is made of a conductive material, e.g., aluminum having an anodically oxidized surface. The main body 16a has a structure to detachably attach the ceiling plate 16b at a bottom portion of the main body 16a.

A gas diffusion space 16c is formed in the main body 16a. A plurality of gas holes 16d is formed in the bottom portion of the main body 16a to be positioned under the gas diffusion space 16c. Gas injection holes 16e are formed through the ceiling plate 16b in a thickness direction thereof. The gas injection holes 16e communicate with the gas holes 16d, respectively. With this configuration, the processing gas supplied to the gas diffusion space 16c is distributed in a shower-like manner into the processing chamber 1 through the gas holes 16d and the gas injection holes 16e.

A gas inlet port 16g for introducing the processing gas into the gas diffusion space 16c is formed in the main body 16a. One end of a gas supply line 15a is connected to the gas inlet port 16g and the other end of the gas supply line 15a is connected to a processing gas supply source (PGS) 15 for supplying a processing gas. A mass flow controller (MFC) 15b and an opening/closing valve V1 are disposed in the gas supply line 15a in that order from an upstream side. The processing gas for plasma etching is supplied from the processing gas supply source 15 to the gas diffusion space 16c through the gas supply line 15a and distributed in a shower-like manner into the processing chamber 1 through the gas holes 16d and the gas injection holes 16e.

A variable DC power supply 72 is electrically connected to the shower head 16 serving as the upper electrode through a low pass filter (LPF) 71. The power supply of the variable DC power supply 72 can be on-off controlled by an on/off switch 73. A current and a voltage of the variable DC power supply 72 and on/off operation of the on/off switch 73 are controlled by a control unit 90 to be described later. For example, when plasma is generated in the processing space by applying the high frequency powers from the first RF power supply 10a and the second RF power supply 10b to the mounting table 2, the on/off switch 73 is turned on by the control unit 90 and a predetermined DC voltage is applied to the shower head 16, if necessary.

A cylindrical ground conductor 1a extends upward from a sidewall of the processing chamber 1 to be located at a position higher than the shower head 16. The cylindrical ground conductor 1a has a ceiling wall at the top thereof.

A gas exhaust port 81 is formed at a bottom portion of the processing chamber 1. A gas exhaust unit (GEU) 83 is connected to the gas exhaust port 81 through a gas exhaust line 82. The gas exhaust unit 83 has a vacuum pump. By operating the vacuum pump, a pressure in the processing chamber 1 can be decreased to a predetermined vacuum level. A loading/unloading port 84 for the wafer W is provided at the sidewall of the processing chamber 1. A gate valve 85 for opening or closing the loading/unloading port 84 is provided at the loading/unloading port 84.

A deposition shield member 86 is provided to extend along an inner surface of the sidewall of the processing chamber 1. The deposition shield member 86 prevents etching by-products (deposits) from being attached to the processing chamber 1. A conductive port (GND block) 89 is provided to a portion of the deposition shield member 86 at a height position substantially same as the height of the wafer W. The conductive port 89 is connected to the ground such that a potential for the ground can be controlled. Due to the presence of the conductive port 89, abnormal discharge can be prevented. A deposition shield member 87 extending along the mounting table 2 is provided at a lower end portion of the deposition shield member 86. The deposition shield members 86 and 87 are detachably provided.

The operation of the substrate processing apparatus 100 configured as described above is generally controlled by the control unit 90. The control unit 90 includes a process controller (PC) 91 having a CPU and configured to control the respective components of the substrate processing apparatus 100, a user interface (UI) 92, and a storage unit (SU) 93.

The user interface 92 includes a keyboard through which a process manager inputs commands to operate the substrate processing apparatus 100, a display for visualizing an operation status of the substrate processing apparatus 100, and the like.

The storage unit 93 stores therein recipes including a control program (software), processing condition data and the like for realizing various processes performed by the substrate processing apparatus 100 under the control of the process controller 91. Moreover, when a command is received from the user interface 92, a necessary recipe is retrieved from the storage unit 93 and executed by the process controller 91, so that a desired process is performed in the substrate forming apparatus 100 under the control of the process controller 91. The recipes including the control program, the processing condition data and the like can be stored in a computer-readable storage medium, e.g., a hard disk, a CD, a flexible disk, a semiconductor memory, or the like, or can be transmitted, when needed, from another apparatus through, e.g., a dedicated line, and used on-line.

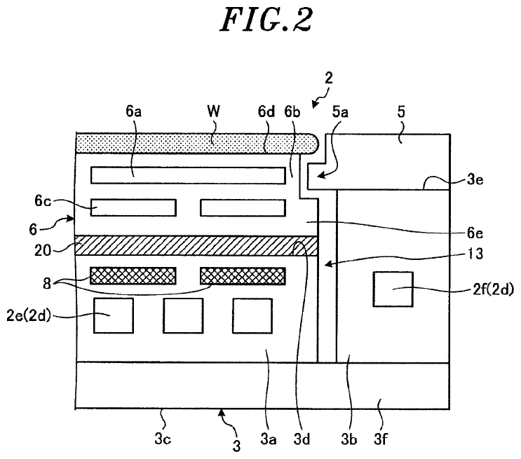

Hereinafter, the main configuration of the mounting table 2 will be described with reference to FIG. 2. FIG. 2 is a cross-sectional view schematically showing an example of a main configuration of the mounting table according to the first embodiment.

The base 3 is formed in, e.g., a substantially cylindrical shape and has a bottom surface 3c and a surface side (upper surfaces 3d and 3e) opposite to the bottom surface 3c. An annular groove 13 is formed on the surface side of the base 3 and extends along the outer periphery of the wafer W mounted on the mounting table 2. In other words, the groove 13 is formed in an annular shape when viewed in a direction orthogonal to the surface of the base 3. The groove 13 may be formed in a continuous annular shape or an intermittent annular shape. The upper portion of the base 3 is divided by a groove 13 into a circular base central portion 3a disposed at a central portion when viewed from a direction orthogonal to the surface of the base 3 and an annular base peripheral portion 3b disposed at a peripheral portion when viewed from a direction orthogonal to the surface of the base 3. The base 3 may include a plurality of parts. For example, the base 3 may include a base central portion 3a, a base peripheral portion 3b, and a base portion 3f forming a lower portion of the base 3.

The base central portion 3a has a circular upper surface 3d for supporting the electrostatic chuck 6. The base peripheral portion 3b has an annular upper surface 3e for supporting the focus ring 5. The upper surface 3e serves as a mounting surface on which the focus ring 5 is mounted. The surface of the base 3 is divided by the groove 13 into the circular upper surface 3d and the annular upper surface 3e.

The heights of the upper surface 3d and the upper surface 3e are appropriately adjusted such that RF power or heat transfer to the wafer W become the same as RF power or heat transfer to the focus ring 5. In other words, although the heights of the upper surface 3d and the upper surface 3e are not the same in FIG. 2, the heights thereof may be the same.

The flow path 2d formed in the base 3 includes an inner flow path 2e disposed at the central portion of the base 3 and an outer flow path 2f disposed at the peripheral portion of the base 3. The inner flow path 2e is formed below the upper surface 3d of the base central portion 3a. The outer flow path 2f is formed below the upper surface 3e of the base peripheral portion 3b. In other words, the inner flow path 2e is disposed below the wafer W and serves to absorb heat of the wafer W, and the outer flow path 2f is disposed below the focus ring 5 and serves to absorb heat of the focus ring 5. The inner flow path 2e and the outer flow path 2f may be connected to different cooling mechanisms to allow coolants of different temperatures to flow therethrough.

The base central portion 3a of the base 3 supports the electrostatic chuck 6 on the upper surface 3d. The electrostatic chuck 6 is disposed on the upper surface 3d through a thickness variable layer 20. The electrostatic chuck 6 has a disk shape and is disposed on the base central portion 3a. A mounting surface 6d for mounting thereon the wafer W is formed on the upper surface of the electrostatic chuck 6. The mounting surface 6d has a circular shape and is brought into contact with the backside of the wafer W to support the disk-shaped wafer W. A flange portion 6e projecting outward in a radial direction of the electrostatic chuck 6 is formed at a lower portion of the electrostatic chuck 6. In other words, the electrostatic chuck 6 has different outer diameters depending on positions on the side surface. The electrostatic chuck 6 has a configuration in which an electrode 6a and a heater(s) 6c are embedded in an insulator 6b. In FIG. 2, the heater(s) 6c is disposed below the electrode 6a. The heating of the mounting surface 6d is controlled by the heater(s) 6c.

The base peripheral edge 3b of the base 3 supports the focus ring 5 on the upper surface 3e. An adhesive layer may be disposed between the base peripheral portion 3b and the focus ring 5. The focus ring 5 that is an annular member is disposed on the base peripheral portion 3b. A protruding portion 5a projecting inward in a radial direction is formed on an inner side surface of the focus ring 5. In other words, the focus ring 5 has different inner diameters depending on regions on the inner side surface. For example, the inner diameter of the focus ring 5 where the protruding portion 5a is not formed is greater than the outer diameter of the wafer W and the outer diameter of the flange portion 6e of the electrostatic chuck 6. On the other hand, the inner diameter of the focus ring 5 where the protruding portion 5a is formed is smaller than the outer diameter of the flange portion 6e of the electrostatic chuck 6 and is greater than the outer diameter of the electrostatic chuck 6 where the flange portion 6e is not formed.

The focus ring 5 is disposed on the upper surface of the base peripheral portion 3b such that the protruding portion 5a is separated from the upper surface of the flange portion 6e of the electrostatic chuck 6 and from the side surface of the electrostatic chuck 6. In other words, a gap is formed between the bottom surface of the protruding portion 5a of the focus ring 5 and the upper surface of the flange portion 6e of the electrostatic chuck 6 and between the side surface of the protruding portion 5a of the focus ring 5 and the side surface of the electrostatic chuck 6 where the flange portion 6e is not formed. The protruding portion 5a of the focus ring is disposed above the groove 13. In other words, when viewed in a direction orthogonal to the mounting surface 6d, the protruding portion 5a is disposed at a position overlapping with the groove 13 and covers the groove 13. Accordingly, it is possible to prevent plasma from flowing into the groove 13.

The thickness variable layer 20 is disposed between the electrostatic chuck 6 and the base central portion 3a. The thickness variable layer 20 has a thickness that changes due to expansion or shrinkage caused by a predetermined process. In the present embodiment, the variable thickness layer 20 contains a shrinkable material, so that the thickness of the variable thickness layer 20 is irreversibly decreased when the shrinkable material shrinks at a high temperature. The shrinkable material may be, e.g., electron beam cross-linked polyolefin resin, electron beam cross-linked polyvinyl chloride resin, electron beam cross-linked polyvinylidene fluoride resin, electron beam cross-linked fluorine elastomer resin, or the like. The shrinkable materials have different shrinkage temperature ranges and different shrinkage rates. The thickness variable layer 20 may serve as an adhesive layer for bonding the electrostatic chuck 6 and the base central portion 3a. For example, the thickness variable layer 20 may have a structure of a sheet containing a shrinkable material in which an adhesive is coated on an upper surface and a bottom surface of the sheet, thereby bonding the electrostatic chuck 6 and the base central portion 3a. As an example of the adhesive, it is possible to use, e.g., a silicon-based adhesive, an epoxy-based adhesive, or an acrylic-based adhesive.

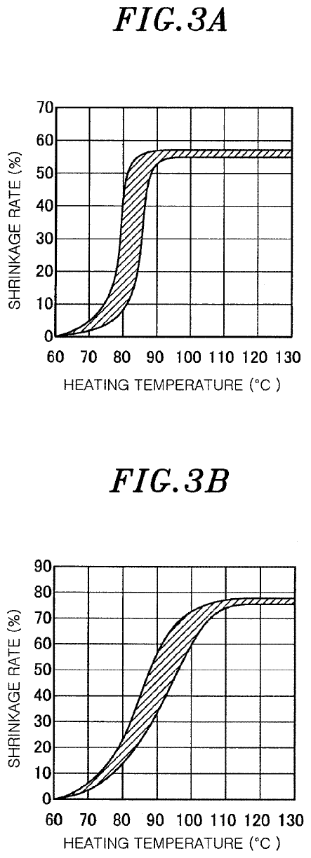

An example of the shrinkable material will be described. FIG. 3A shows an example of the shrinkage of the shrinkable material according to the first embodiment depending on a temperature. FIG. 3A shows a relationship between the temperature and the shrinkage rate in the case of using the electron beam cross-linked polyolefin resin as the shrinkable material. In FIG. 3A, a temperature tolerance with respect to the shrinkage rate is about ±5° C. The electron beam cross-linked polyolefin resin shown in FIG. 3A starts shrinking at about 60° C. and shrinks by 55% at about 90° C. The electron beam cross-linked polyolefin resin shrinks depending on the temperature in a range from about 60° C. to about 90° C.

FIG. 3B shows another example of the shrinkage of the shrinkable material according to the first embodiment depending on the temperature. FIG. 3B shows a relationship between the temperature and the shrinkage rate in the case of using another electron beam cross-linked polyolefin resin as the shrinkable material. In FIG. 3B, a temperature tolerance with respect to the shrinkage rate is about ±5° C. The electron beam cross-linked polyolefin resin shown in FIG. 3B starts shrinking at about 60° C. and shrinks by 75% at about 120° C. The electron beam cross-linked polyolefin resin shrinks depending on the temperature in a range from about 60° C. to about 120° C.

For example, when the thickness variable layer 20 is a sheet having a thickness of 4 mm and made of electron beam cross-linked polyolefin resin having characteristics shown in FIG. 3A, the thickness variable layer 20 has a thickness of 4 mm at a room temperature but shrinks to have a thickness of 2.2 mm when it is heated to 90° C. or higher.

By mixing the shrinkable materials into the thickness variable layer 20, the thickness variable layer 20 shrinks depending on the temperature, thereby lowering the electrostatic chuck 6. Further, the shrinkage temperature range or the temperature-based shrinkage rate of the thickness variable layer 20 can be changed by adjusting types or amounts of shrinkable materials to be mixed. In addition, for a material forming the thickness variable layer 20, it is possible to use, e.g., thermosetting resin such as phenol resin, epoxy resin, melamine resin, urea resin, unsaturated polyester resin, diallyl phthalate resin, polyurethane resin, silicon resin, or the like.

Referring back to FIG. 2, a heater(s) 8 is arranged in the base central portion 3a at a position corresponding to the thickness variable layer 20. For example, the heater(s) 8 is arranged above the flow path 2e in the base central portion 3a to face the thickness variable layer 20. The heater(s) 8 generates heat by power supplied from the heater power supply 9 shown in FIG. 1. The control unit 90 controls the power supplied from the heater power supply 9 to the heater(s) 8 to control the temperature of the heater(s) 8. By controlling the temperature of the heater(s) 8, the control unit 90 controls the shrinkage rate of the thickness variable layer 20, thereby controlling the downward movement amount of the electrostatic chuck 6.

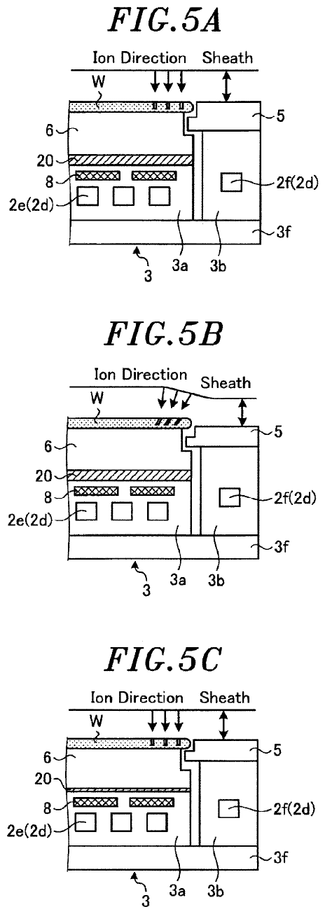

Next, the operations and the effects of the substrate processing apparatus 100 according to the first embodiment will be described. FIGS. 5A to 5C explain examples of the operations and the effects of the first embodiment.

In the substrate processing apparatus 100, when plasma processing such as plasma etching or the like is performed, the focus ring 5 is consumed. When the focus ring 5 is consumed, the thickness of the plasma sheath near the focus ring 5 is reduced. Therefore, the height of the plasma sheath with respect to the wafer W is changed, which also changes the processing characteristics. For example, in the case of using a new focus ring 5, the height of the plasma sheath above the upper surface of the focus ring 5 is substantially the same as the height of the plasma sheath above the upper surface of the wafer W and, thus, ions having positive charges are vertically incident on the wafer W and holes are etched normally, as shown in FIG. 5A.

However, when the focus ring 5 is consumed, the height of the plasma sheath above the focus ring 5 is reduced and, thus, the incident angle of ions having positive charges to the wafer W changes, as shown in FIG. 5B. The change in the incident angle of the ions having positive charges leads to changes in etching characteristics. For example, shape abnormality such as tilting occurs in a hole(s) etched at the peripheral portion of the wafer W. The tilting is an abnormality in which a hole is etched obliquely.

Accordingly, the control unit 90 reduces the thickness of the thickness variable layer 20 by controlling the temperature of the heater(s) 8 at predetermined timings, thereby lowering the electrostatic chuck 6.

For example, the shrinkage rate of the thickness variable layer 20, at which the heights of the plasma sheath become substantially the same above the upper surface of the focus ring 5 and above the upper surface of the wafer W, is determined in advance depending on a processing time during which the plasma processing is performed. Then, for each processing time, the temperature of the heater(s) 8 at which the determined shrinkage rate is obtained is stored as control information on the thickness of the thickness variable layer 20 in the storage unit 93. At each timing when the plasma processing is performed for a predetermined period of time, the process controller 91 reads out the temperature of the heater(s) 8 corresponding to the processing time of the plasma processing from the control information stored in the storage unit 93. The process controller 91 controls the power supplied from the heater power supply 9 so that the temperature of the heater(s) 8 reaches the read-out temperature.

Alternatively, for example, the shrinkage rate of the thickness variable layer 20, at which the heights of the plasma sheath become substantially the same above the upper surface of the focus ring 5 and above the upper surface of the wafer W, is determined in advance depending on a predetermined number of wafers W subjected to the plasma processing. Then, for each predetermined number of wafers W, the temperature of the heater(s) 8 at which the determined shrinkage rate is obtained is stored as control information on the thickness of the thickness variable layer 20 in the storage unit 93. At each timing when the plasma processing is performed for the predetermined number of wafers W, the process controller 91 reads out the temperature of the heater(s) 8 corresponding to the number of processed wafers W from the control information stored in the storage unit 93. Further, the process controller 91 controls the power supplied from the heater power supply 9 so that the temperature of the heater(s) 8 reaches the read-out temperature.

Therefore, the thickness of the thickness variable layer 20 is reduced and the electrostatic chuck 6 is moved downwardly. As a result, as shown in FIG. 5C, the height of the plasma sheath above the upper surface of the focus ring 5 becomes substantially the same as the height of the plasma sheath above the upper surface of the wafer W, and ions having positive charges are vertically incident on the wafer W and holes are normally (vertically) etched. With such configuration, the focus ring 5 can be used continuously, and the replacement cycle of the focus ring 5 can be extended.

As described above, the substrate processing apparatus 100 can extend the replacement cycle of the focus ring 5 with a simple configuration that allows the thickness of the thickness variable layer 20 to be reduced.

The shape of the hole(s) of the wafer W etched by the substrate processing apparatus 100 may be measured by an external measurement device. Then, the control unit 90 controls the temperature of the heater(s) 8 to reduce the thickness of the thickness variable layer 20 based on the measurement result of the measurement device, thereby lowering the electrostatic chuck 6.

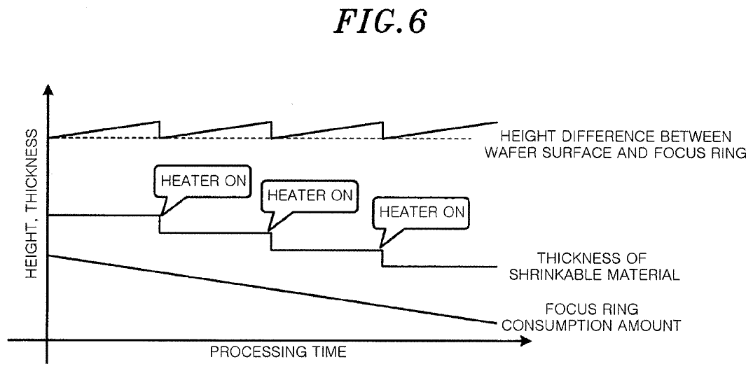

FIG. 6 shows a flow of the thickness control of the thickness variable layer 20 according to the first embodiment. The focus ring (FR) 5 is consumed as the processing time of the plasma processing, e.g., the plasma etching, elapses. Therefore, the height difference between the upper surface of the wafer W and the upper surface of the focus ring 5 is increased. Accordingly, the control unit 90 turns on the heater(s) 8 at predetermined timings to shrink the shrinkable material of the thickness variable layer 20 and reduce the thickness of the thickness variable layer 20. Thus, the electrostatic chuck 6 is lowered such that the height difference between the upper surface of the wafer W and the upper surface of the focus ring 5 becomes the initial difference therebetween. As a consequence, even when the focus ring 5 is consumed as the processing time of the plasma processing elapses, it is possible to maintain a small height difference between the upper surface of the wafer W and the upper surface of the focus ring 5.

Here, it is considered the case that a mechanical mechanism driven by an actuator is used in the substrate processing apparatus 100 to raise and lower the electrostatic chuck 6. However, the mechanical mechanism is limited to about 6 um elevation accuracy and, thus, it is difficult to raise or lower the electrostatic chuck 6 by a distance requiring an accuracy of a value less than 6 μm.

In contrast, the shrinkage amount of the thickness variable layer 20 according to the embodiment can be finely adjusted and, thus, the electrostatic chuck 6 can be raised and lowered with high accuracy.

For example, a sheet that is mixed with multiple shrinkable materials having different shrinkage completion temperatures is disposed as the thickness variable layer 20 between the electrostatic chuck 6 and the base central portion 3a. For example, the shrinkable materials having the shrinkage completion temperatures of 90° C., 110° C., 130° C., and 150° C. are mixed in the sheet. Each of the shrinkage start temperatures of the shrinkable materials is set to be higher than an etching temperature. In this example, the etching temperature is set to be lower than or equal to 60° C. Alternatively, a plurality of sheets, each of which is made of shrinkable materials having different shrinkage completion temperatures, may be laminated. Further, when directions of the shrinkage of the shrinkable materials are known and predetermined, the sheet(s) is mixed or disposed such that directions of the shrinkage are set to be the same as the direction in which the electrostatic chuck 6 is raised and lowered.

Specifically, in the case of the electron beam cross-linked polyolefin resin shown in FIG. 3A having a shrinkage completion temperature of 90° C. and a shrinkage rate of 55%, a film thickness of a resin sheet (polyolefin resin sheet) initially having a film thickness of 1 mm becomes 0.45 mm when the resin sheet is heated to 90° C. or higher. These characteristics will be utilized.

For example, for the thickness variable layer 20, a sheet A formed by laminating the following sheets 1 to 4 having different shrinkage completion temperatures is used.

Sheet 1: Polyolefin resin sheet having a shrinkage completion temperature of 90° C., a shrinkage rate of 55%, and a film thickness of 1 mm

Sheet 2: Polyolefin resin sheet having a shrinkage completion temperature of 110° C., a shrinkage rate of 55%, a film thickness of 1 mm

Sheet 3: Polyolefin resin sheet having a shrinkage completion temperature of 130° C., a shrinkage rate of 55%, and a film thickness of 1 mm

Sheet 4: Polyolefin resin sheet having a shrinkage completion temperature 150° C., a shrinkage rate of 55%, and a film thickness of 1 mm

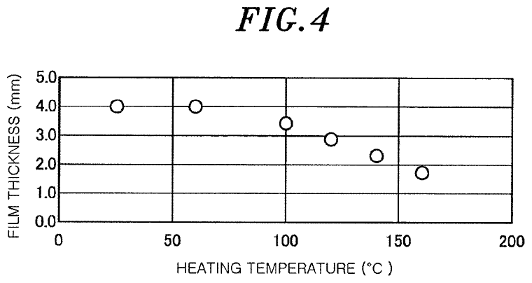

The sheet A has a film thickness of 4 mm at room temperature. When the sheet A is heated to 100° C., the film thickness of the sheet A becomes 3.45 mm. When the sheet A is heated to 120° C., the film thickness of the sheet A becomes 2.90 mm. When the sheet A is heated to 140° C., the film thickness of the sheet A becomes 2.35 mm. When the sheet A is heated to 160° C., the film thickness of the sheet A becomes 1.80 mm. Therefore, as shown in FIG. 4, the thickness of the sheet A can be reduced by 550 μm at 20° C. intervals in a range starting from 100° C. to 160° C.

The thickness can be changed in smaller increments. For example, for the thickness variable layer 20, a sheet B formed by laminating the following sheets 5 to 8 having different shrinkage completion temperatures is used.

Sheet 5: Polyolefin resin sheet having a shrinkage completion temperature of 90° C., a shrinkage rate of 55%, and a film thickness of 0.1 mm

Sheet 6: Polyolefin resin sheet having a shrinkage completion temperature of 110° C., a shrinkage rate of 55%, and a film thickness of 0.1 mm

Sheet 7: Polyolefin resin sheet having a shrinkage completion temperature of 130° C., a shrinkage rate of 55%, and a film thickness of 0.1 mm

Sheet 8: Polyolefin resin sheet having a shrinkage completion temperature of 150° C., a shrinkage rate of 55%, and a film thickness of 0.1 mm

The sheet B has a film thickness of 0.4 mm at room temperature. When the sheet B is heated to 100° C., the film thickness of the sheet B becomes 0.345 mm. When the sheet B is heated to 120° C., the film thickness of the sheet B becomes 0.290 mm. When the sheet B is heated to 140° C., the film thickness of the sheet B becomes 0.235 mm. When the sheet B is heated to 160° C., the film thickness of the sheet B becomes 0.180 mm. Therefore, the thickness of the sheet B can be reduced by 55 μm at 20° C. intervals in a range starting from 100° C. to 160° C.

The thickness can be changed in much smaller increments. For example, for the thickness variable layer 20, a sheet C formed by laminating the following sheets 9 to 12 having different shrinkage completion temperatures is used.

Sheet 9: Polyolefin resin sheet having a shrinkage completion temperature of 90° C., a shrinkage rate of 55%, and a film thickness of 0.01 mm

Sheet 10: Polyolefin resin sheet having a shrinkage completion temperature of 110° C., a shrinkage rate of 55%, and a film thickness of 0.01 mm

Sheet 11: Polyolefin resin sheet having a shrinkage completion temperature of 130° C., a shrinkage ratio of 55%, and a film thickness of 0.01 mm

Sheet 12: Polyolefin resin sheet having a shrinkage completion temperature of 150° C., a shrinkage rate of 55%, and a film thickness of 0.01 mm

The sheet C has a film thickness of 0.04 mm at room temperature. When the sheet C is heated to 100° C., the film thickness of the sheet C becomes 0.0345 mm. When the sheet C is heated to 120° C., the film thickness of the sheet C becomes 0.0290 mm. When the sheet C is heated to 140° C., the film thickness of the sheet C becomes 0.0235 mm. When the sheet C is heated to 160° C., the film thickness of the sheet C becomes 0.0180 mm. Therefore, the thickness of the sheet C can be reduced by 5.5 μm at 20° C. intervals in a range starting from 100° C. to 160° C.

Next, the case of mixing materials, instead of laminating materials, will be described. For example, for the thickness variable layer 20, a sheet D having a thickness of 1 mm is formed of resin containing the following materials 1 to 5 having different shrinkage completion temperatures.

Material 1: 1% polyolefin resin having a shrinkage completion temperature 90° C. and a shrinkage rate of 55%

Material 2: 1% polyolefin resin having a shrinkage completion temperature 110° C. and a shrinkage rate of 55%

Material 3: 1% polyolefin resin having a shrinkage completion temperature 130° C. and a shrinkage rate of 55%

Material 4: 1% polyolefin resin having a shrinkage completion temperature 150° C. and a shrinkage rate of 55′

Material 5: 96% non-shrinkable resin

The sheet D has a film thickness of 1 mm at room temperature. When the sheet D is heated to 100° C., the film thickness of the sheet D becomes 0.9945. When the sheet D is heated to 120° C., the film thickness of the sheet D becomes 0.9890 mm. When the sheet D is heated to 140° C., the film thickness of the sheet D becomes 0.9835 mm. When the sheet D is heated to 160° C., the film thickness of the sheet D becomes 0.9780 mm. Therefore, the thickness of the sheet D can be reduced by 5.5 μm at 20° C. intervals in a range starting from 100° C. to 160° C.

The thickness can be changed in smaller increments. For example, as for the thickness variable layer 20, a sheet E having a thickness of 1 mm is formed of resin containing the following materials 6 to 10 having different shrinkage completion temperatures.

Material 6: 0.1% polyolefin resin having a shrinkage completion temperature 90° C. and a shrinkage rate of 55%

Material 7: 0.1% polyolefin resin having a shrinkage completion temperature 100° C. and a shrinkage rate of 55%

Material 8: 0.1% polyolefin resin having a shrinkage completion temperature 130° C. and a shrinkage rate of 55%

Material 9: 0.1% polyolefin resin having a shrinkage completion temperature 150° C. and a shrinkage rate of 55%

Material 10: 99.6% non-shrinkable resin

The sheet E has a film thickness of 1 mm at room temperature. When the sheet E is heated to 100° C., the film thickness of the sheet E becomes 0.99945 mm. When the sheet E is heated to 120° C., the film thickness of the sheet E becomes 0.99890 mm. When the sheet E is heated to 140° C., the film thickness of the sheet E becomes 0.99835 mm. When the sheet E is heated to 160° C., the film thickness of the sheet E becomes 0.99780 mm. Therefore, the thickness of the sheet E can be reduced by 0.55 μm at 20° C. intervals in a range starting from 100° C. to 160° C.

Next, the case where the shrinkage start temperature and the shrinkage completion temperature have a wide range will be described. For example, for the thickness variable layer 20, a sheet F having a thickness of 1 mm is formed by mixing 1% polyolefin resin having a shrinkage start temperature of 60° C., a shrinkage completion temperature of 120° C., and a shrinkage rate of 75% shown in FIG. 3B with polyolefin resin having a shrinkage completion temperature of 140° C.

The sheet F has a film thickness of 1 mm at room temperature. When the sheet F is heated to 70° C., the film thickness of the sheet F is reduced by 0.0005 mm (0.5 m). When the sheet F is heated to 100° C., the film thickness of the sheet F is reduced by 0.0065 mm (6.5 μm). When the sheet F is heated to 130° C., the film thickness of the sheet E is reduced by 0.0075 mm (7.5 μm). On the assumption that the relationship between the temperature and the film thickness is linear in a temperature range from 70° C. to 100° C., the film thickness of the sheet F is reduced by 0.2 μm per 1° C.

Since the shrinkage amount of the thickness variable layer 20 according to the embodiment can be finely adjusted, the electrostatic chuck 6 can be raised and lowered with high accuracy. Although the electrostatic chuck 6 can be raised and lowered with high accuracy by finely adjusting the shrinkage amount of the thickness variable layer 20 as described above, the overall stroke (movable range) may be small. Therefore, the substrate processing apparatus 100 may alternatively use both of the mechanical mechanism and the thickness variable layer 20 to control the height of the electrostatic chuck 6. For example, when the electrostatic chuck 6 is to be lowered by a large amount, the substrate processing apparatus 100 may use the mechanical mechanism for rough adjustment and use the thickness variable layer 20 for fine adjustment.

Further, the film thickness of the thickness variable layer 20 may be measured by measuring the capacitance between the electrode 6a in the electrostatic chuck 6 and the heater 8 in the base 3. Here, when the thickness of the thickness variable layer 20 is denoted by “d” and the capacitance between the electrode 6a and the heater 8 is denoted by “C”, the characteristic that “C” is in inverse proportion to “d” can be utilized.

As described above, the substrate processing apparatus 100 of the present embodiment includes the electrostatic chuck 6 (substrate mounting unit), the base 3 (support unit), the thickness variable layer 20, and the control unit 90. The upper surface of the electrostatic chuck 6 serves as the mounting surface on which the wafer W is mounted. The base 3 has therein the flow path 2d for a heat transfer medium, and supports the electrostatic chuck 6. The thickness variable layer 20 is disposed between the electrostatic chuck 6 and the base 3 and has a thickness that changes due to shrinkage caused by a predetermined process. The control unit 90 controls the thickness of the thickness variable layer 20 by performing the predetermined process. Therefore, the substrate processing apparatus 100 can extend the replacement cycle of the focus ring 5 with a simple configuration.

The thickness of the thickness variable layer 20 is irreversibly changed when the thickness variable layer 20 shrinks by the predetermined process. Therefore, the substrate processing apparatus 100 can adjust the height of the electrostatic chuck 6 using the thickness variable layer 20 without a complicated configuration such as a mechanical mechanism or the like.

The thickness variable layer 20 shrinks depending on the temperature, so that its thickness changes. The heater 8 is arranged in the base 3 at a position corresponding to the thickness variable layer 20. The control unit 90 controls the thickness of the thickness variable layer 20 by performing the predetermined process, e.g., by controlling the temperature of the thickness variable layer 20 using the heater 8. Therefore, the substrate processing apparatus 100 can control the thickness of the thickness variable layer 20 simply by controlling the temperature of the thickness variable layer 20 using the heater 8, so that the height of the electrostatic chuck 6 can be controlled.

The thickness variable layer 20 shrinks depending on the temperature, so that its thickness is reduced. The control unit 90 reduces the thickness of the thickness variable layer 20 by controlling the temperature of the thickness variable layer 20 using the heater 8 at predetermined timings. Accordingly, the substrate processing apparatus 100 can maintain a small height difference between the upper surface of the wafer W and the upper surface of the focus ring 5 even when the focus ring 5 is consumed as the processing time of the plasma processing elapses.

### Second Embodiment

Next, a second embodiment will be described. A schematic configuration of the substrate processing apparatus 100 according to the second embodiment is the same as that of the substrate processing apparatus 100 according to the first embodiment shown in FIG. 1. Therefore, the redundant description thereof will be omitted.

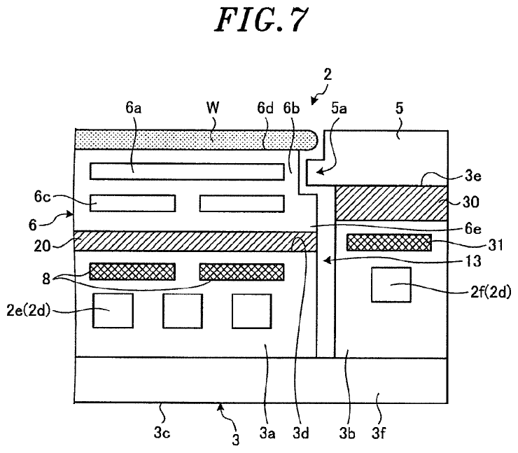

FIG. 7 is a cross-sectional view schematically showing an example of a main configuration of the mounting table according to the second embodiment. The main configuration of the mounting table 2 according to the second embodiment is partially the same as that of the mounting table 2 according to the first embodiment shown in FIG. 2. Therefore, like reference numerals will be used for like parts, and the differences will be mainly described.

In the mounting table 2 according to the second embodiment, a thickness variable layer 30 is disposed between the base peripheral portion 3b and the focus ring 5. The thickness variable layer 30 expands or shrinks by a predetermined process. In the present embodiment, the thickness variable layer 30 is made of mixed expandable materials. Therefore, when the expandable materials expand at a high temperature, the thickness of the thickness variable layer 30 is irreversibly increased. The expandable materials may be, e.g., expandable graphite (flake graphite intercalation compound), silicon rubber and the like. Silicone rubber has a siloxane bond as a main chain and a methyl group as a side chain. Expandable graphite is expanded when a substance intercalated between layers of graphite is burned and gasified by heating to thereby forcibly expand an interlayer spacing. When silicon rubber is heated, siloxane bonds or methyl group bonds are broken by thermal degradation. Therefore, a large number of crosslinks are generated at the main chain. Although the crosslinks are re-bonded, the bonding angle is changed and, thus, it is difficult to maintain the siloxane structure. Accordingly, the polymer structure collapses and expansion tends to occur. If the temperature is further increased, the siloxane bond as the main chain is broken by thermal degradation, and the collapse of the polymer structure is accelerated and new expansion occurs. The thickness variable layer 30 may serve as an adhesive layer for bonding the base peripheral portion 3b and the focus ring 5. For example, the thickness variable layer 30 may have a structure in which an adhesive is coated on an upper surface and a bottom surface of the sheet containing the expandable material to adhere the base peripheral portion 3b and the focus ring 5.

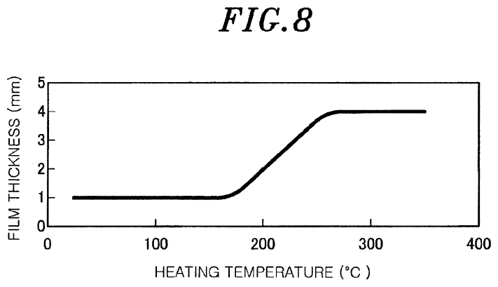

For example, as for the thickness variable layer 30, an expandable graphite sheet having a thickness of 1 mm is used. FIG. 8 shows an example of changes in the film thickness of the thickness variable layer 30 with the temperature according to the second embodiment. In this case, as shown in FIG. 8, the thickness variable layer 30 starts to expand from 1 mm at about 170° C. and expands to 4 mm by 300% at about 260° C. The thickness variable layer 30 expands depending on the temperature in a range from 170° C. to about 260° C.

The thickness variable layer 30 made of mixed expandable materials expands depending on the temperature to raise the focus ring 5. Further, the expandable temperature range or the temperature-based expansion rate of the thickness variable layer 30 can be changed by adjusting types or amounts of expandable materials to be mixed.

Referring back to FIG. 7, a heater(s) 31 is arranged in the base peripheral portion 3b at a position corresponding to the thickness variable layer 30. For example, the heater(s) 31 is arranged above the flow paths 2f and 2e in the base peripheral portion 3b to face the thickness variable layer 30. The heater(s) 31 generates heat by power supplied from the heater power supply 9 shown in FIG. 1. The control unit 90 controls the temperature of the heater(s) 31 by controlling the power supplied from the heater power supply 9 to the heater(s) 31. The control unit 90 controls the expansion rate of the thickness variable layer 30 by controlling the temperature of the heater(s) 31, thereby controlling the upward movement amount of the focus ring 5.

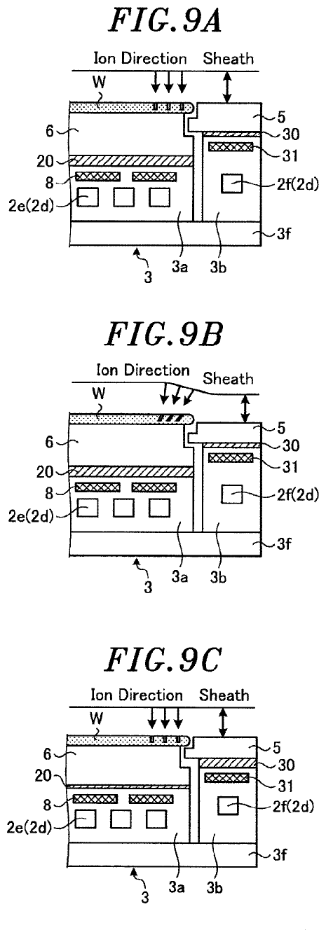

Next, the operations and the effects of the substrate processing apparatus 100 according to the second embodiment will be described. FIGS. 9A to 9C explain examples of the operations and the effects of the second embodiment.

In the substrate processing apparatus 100, when plasma processing such as plasma etching or the like is performed, the focus ring 5 is consumed. When the focus ring 5 is consumed, the thickness of the plasma sheath near the focus ring 5 is reduced. Therefore, the height of the plasma sheath with respect to the wafer W is changed, which also changes the processing characteristics. For example, in the case of using a new focus ring 5, the height of the plasma sheath above the upper surface of the focus ring 5 is substantially the same as the height of the plasma sheath above the upper surface of the wafer W and, thus, ions having positive charges are vertically incident on the wafer W and holes are etched normally, as shown in FIG. 9A.

However, when the focus ring 5 is consumed, the height of the plasma sheath above the focus ring 5 is reduced and, thus, the incident angle of ions having positive charges to the peripheral portion of the wafer W is changed, as shown in FIG. 9B. The change in the incident angle of the ions having positive charges leads to changes in etching characteristics. For example, shape abnormality such as tilting occurs in a hole(s) etched at the peripheral portion of the wafer W. The tilting is an abnormality in which a hole is etched obliquely.

Accordingly, the control unit 90 lowers the electrostatic chuck 6 by reducing the thickness of the thickness variable layer 20 and raises the focus ring 5 by increasing the thickness of the thickness variable layer 30 by controlling the temperatures of the heaters 8 and 31 at predetermined timings. For example, the shrinkage rate of the thickness variable layer 20 and the expansion rate of the thickness variable layer 30, at which the heights of the plasma sheath become substantially the same above the upper surface of the focus ring 5 and above the upper surface of the wafer W, are determined in advance depending on a processing time during which the plasma processing is performed. Then, for each processing time, the temperature of the heater(s) 8 at which the determined shrinkage rate is obtained and the temperature of the heater(s) 31 at which the determined expansion rate is obtained are stored as control information on the thicknesses of the thickness variable layers 20 and 30 in the storage unit 93. At each timing when the plasma processing is performed for a predetermined period of time, the process controller 91 reads out the temperatures of the heaters 8 and 31 corresponding to the processing time of the plasma processing from the control information stored in the storage unit 93. The process controller 91 controls the power supplied from the heater power supply 9 so that the temperatures of the heaters 8 and 31 reach the read-out temperatures. Alternatively, for example, the shrinkage rate of the thickness variable layer 20 and the expansion rate of the thickness variable layer 30, at which the heights of the plasma sheath become substantially the same above the upper surface of the focus ring 5 and above the upper surface of the wafer W, are determined in advance depending on a predetermined number of wafers W subjected to the plasma processing. Then, for each predetermined number of wafers W, the temperature of the heater 8 at which the determined shrinkage rate is obtained and the temperature of the heater 31 at which the determined expansion rate is obtained are stored as control information on the thicknesses of the thickness variable layers 20 and 30 in the storage unit 93. At each timing when the plasma processing is performed for the predetermined number of wafers W, the process controller 91 reads out the temperatures of the heaters 8 and 31 corresponding to the number of processed wafers W from the control information stored in the storage unit 93. Further, the process controller 91 controls the power supplied from the heater power supply 9 so that the temperatures of the heaters 8 and 31 reach the read-out temperatures.

Therefore, the thickness of the thickness variable layer 20 is reduced and the electrostatic chuck 6 is moved downwardly. Also, the thickness of the thickness variable layer 30 is increased and the focus ring 5 is moved upwardly. As a result, as shown in FIG. 9C, the height of the plasma sheath above the upper surface of the focus ring 5 becomes substantially the same as the height of the plasma sheath above the upper surface of the wafer W, and ions having positive charges are vertically incident on the wafer W and holes are normally (vertically) etched. With such configuration, the focus ring 5 can be used continuously, and the replacement cycle of the focus ring 5 can be extended.

As described above, the substrate processing apparatus 100 can extend the replacement cycle of the focus ring 5 with a simple configuration that allows the thickness of the thickness variable layer 20 to be reduced and the thickness of the thickness variable layer 30 to be increased.

The shape of the hole(s) of the wafer W etched by the substrate processing apparatus 100 may be measured by an external measurement device. Then, the control unit 90 controls the temperature of the heaters 8 and 31 to reduce the thickness of the thickness variable layer 20 and increase the thickness of the thickness variable layer 30 based on the measurement result of the measurement device, thereby lowering the electrostatic chuck 6 and raising the focus ring 5.

Here, it is considered the case that a mechanical mechanism driven by an actuator is used in the substrate processing apparatus 100 to raise and lower the focus ring 5. However, the mechanical mechanism is limited to about 6 μm elevation accuracy and, thus, it is difficult to raise or lower the focus ring 5 by a distance requiring an accuracy of a value less than 6 μm.

In contrast, the expansion amount of the thickness variable layer 30 according to the embodiment can be finely adjusted and, thus, the focus ring 5 can be raised and lowered with high accuracy.

Specifically, in the case of a sheet made of expandable graphite having an expansion start temperature of 170° C. and an expansion completion temperature of 260° C. shown in FIG. 8, a film thickness of the sheet initially having a film thickness of 1 mm becomes 2 mm when the sheet is heated to 200° C., 3 mm when the sheet is heated to 230° C., and 4 mm when the sheet is heated to 260° C. or higher. These characteristics will be utilized.

For example, as for the thickness variable layer 30, a sheet G made of resin containing 1% expandable graphite shown in FIG. 8 is used.

The sheet G has a film thickness of 1.02 mm when heated to 200° C. The sheet G has the film thickness of 1.03 when heated to 230° C. The sheet G has the film thickness of 1.04 mm when heated to 260° C. Therefore, the thickness of the sheet G can be increased by 40 μm at 30° C. intervals in a range starting from 200° C. to 260° C.

The thickness can be changed in smaller increments. For example, as for the thickness variable layer 30, a sheet H made of resin containing 0.1% expandable graphite shown in FIG. 8 is used.

The sheet H has a film thickness of 1.002 mm when heated to 200° C. The sheet H has the film thickness of 1.003 when heated to 230° C. The sheet H has the film thickness of 1.004 mm when heated to 260° C. Therefore, the thickness of the sheet H can be increased by 4 μm at 30° C. intervals in a range starting from 200° C. to 260° C.

Since the expansion amount of the thickness variable layer 30 according to the embodiment can be finely adjusted, the focus ring 5 can be raised with high accuracy. Although the focus ring 5 can be raised with high accuracy by finely adjusting the expansion amount of the thickness variable layer 30 as described above, the overall stroke (movable range) may be small. Therefore, the substrate processing apparatus 100 may alternatively use both of the mechanical mechanism and the thickness variable layer 30 to control the height of the focus ring 5. For example, when the focus ring 5 is to be raised by a large amount, the substrate processing apparatus 100 may use the mechanical amount, the mechanism for rough adjustment and use the thickness variable layer 30 for fine adjustment.

The substrate processing apparatus 100 of the present embodiment further includes the base peripheral portion 3b (focus ring mounting portion) and the thickness variable layer 30 (second thickness variable layer). The base peripheral portion 3b is disposed to surround the electrostatic chuck 6, and the upper surface of the base peripheral portion 3b serves as a mounting surface on which the focus ring 5 is mounted. The thickness variable layer 30 is disposed between the focus ring 5 and the base peripheral portion 3b. The thickness variable layer 30 expands by a predetermined process and, thus, its thickness is changed. The control unit 90 controls the thickness of the thickness variable layer 30 by performing the predetermined process. Accordingly, the substrate processing system 100 of the present embodiment can extend the replacement cycle of the focus ring 5 with a simple configuration.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures.

For example, in the above-described embodiments, the case where the substrate processing apparatus 100 is a plasma processing apparatus for performing the plasma etching has been described as an example. However, the present disclosure is not limited thereto. For example, the substrate processing apparatus 100 may be a substrate processing apparatus for performing a film formation or improving a film quality. In addition, although the above-described substrate processing apparatus 100 is a capacitively coupled plasma processing apparatus, the thickness variable layers 20 and 30 may be employed in any plasma processing apparatus. For example, the substrate processing apparatus 100 may be any type of plasma processing apparatus, such as an inductively coupled plasma processing apparatus or a plasma processing apparatus for exciting gas by surface waves such as microwaves.

In the above-described embodiments, the case where the thickness of the thickness variable layer 20 made of mixed shrinkable materials is irreversibly reduced has been described as an example. However, the present disclosure is not limited thereto. For example, the substrate processing apparatus 100 may employ the thickness of the thickness variable layer 20 made of mixed expandable materials whose thickness is irreversibly increased. For example, in the substrate processing apparatus 100, when a thickness of a new focus ring 5 is greater than a reference thickness, the height of the plasma sheath near the focus ring 5 becomes higher than that near the upper surface of the wafer W, and incident angle of ions having positive charges is changed. Thus, etching characteristics are changed due to the change of the incident angle of the ions having positive charges. For example, shape abnormality such as tilting occurs in a hole etched at the peripheral portion of the wafer W. In this case, the substrate processing apparatus 100 is controlled to increase the thickness of the thickness variable layer 20 by expanding the thickness variable layer 20, thereby raising the electrostatic chuck 6. Therefore, the heights of the plasma sheath become substantially the same above the upper surface of the focus ring 5 and above the upper surface of the wafer W. Accordingly, ions having positive charges are vertically incident on the wafer W, and holes are normally etched. Further, the substrate processing apparatus 100 is controlled to intentionally change the processing characteristics by increasing the thickness of the thickness variable layer 20.

Further, in the above-described embodiments, the case where the thickness of the thickness variable layer 30 made of mixed expandable materials is irreversibly increased has been described as an example. However, the present disclosure is not limited thereto. For example, the substrate processing apparatus 100 may employ the thickness of the thickness variable layer 30 made of mixed shrinkable materials whose thickness is irreversibly reduced. For example, in the case that the thicknesses of the thickness variable layers 20 and 30 are reduced due to the shrinkage thereof, the substrate processing apparatus 100 is controlled to raise the focus ring 5 to be positioned relatively higher than the wafer W by setting the shrinkage rate of the thickness variable layer 30 to be lower than that of the thickness variable layer 20. Further, the substrate processing apparatus 100 is controlled to intentionally change the processing characteristics by reducing the thickness of the thickness variable layer 30.

Although the above-described embodiments have described, as an example, the case where the shrinkable material and the expandable material shrink and expand depending on the temperature, the present disclosure is not limited to thereto. For example, the shrinkable material and the expandable material may shrink and expand by another process such as plasma processing and the like. As an example, it is possible to use a metal material that expands when coupled with oxygen. For example, the substrate processing apparatus 100 may employ the metal material that expands when coupled with oxygen as the expandable material of the thickness variable layer 30. Then, the substrate processing apparatus 100 is controlled to supply oxygen gas from the shower head 16 to generate oxygen plasma and increase the thickness of the thickness variable layer 30 by expanding the metal material of the thickness variable layer 30 by allowing oxygen radicals of the oxygen plasma to be coupled with the metal material. In this case, the metal material may contain any metal element among Al, Ti, Co, Ni, Y, Zr, Hf, Ta, and W. In another example, it is possible to use a material containing a hydrogen occlusion alloy which expands in volume by absorbing hydrogen. For example, the substrate processing apparatus 100 may employ a metal material that expands when coupled with hydrogen as the expandable material of the thickness variable layer 30. Then, the substrate processing apparatus 100 controlled to supply hydrogen gas from the shower head 16 and increase the thickness of the thickness variable layer 30 by expanding the metal material of the thickness variable layer 30 by absorbing hydrogen into the metal material.

Although a semiconductor wafer has been described as an example of a target substrate to be processed in the above-described embodiments, the semiconductor wafer may be silicon or may be a compound semiconductor such as GaAs, SiC, GaN, or the like. Further, a ceramic substrate and a glass substrate used for flat panel display (FPD) such as a liquid crystal display or the like may be employed as the target substrate without being limited to the semiconductor wafer.

In the above-described embodiments, the case where the base central portion 3a and the base peripheral portion 3b are divided by the groove 13 has been described as an example. However, the present disclosure is not limited thereto. For example, a structure of the base central portion 3a and the base peripheral portion 3b may have a physically continuous structure, and the base peripheral portion 3b may support the focus ring 5.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A substrate processing apparatus, comprising:
a substrate mounting unit having an upper surface that serves as a mounting surface on which a target substrate to be processed is mounted;
a support unit having therein a flow path for a heat transfer medium and configured to support the substrate mounting unit;
a thickness variable layer disposed between the substrate mounting unit and the support unit and having a thickness that changes due to expansion or shrinkage caused by a predetermined process; and
a control unit configured to control the thickness of the thickness variable layer by performing the predetermined process.

2. The substrate processing apparatus of claim 1, wherein the thickness of the thickness variable layer is irreversibly changed when the thickness variable layer shrinks or expands by the predetermined process.

3. The substrate processing apparatus of claim 1, wherein the thickness variable layer expands or shrinks depending on a temperature to thereby change the thickness of the thickness variable layer,
the support unit has therein one or more heaters arranged at positions corresponding to the thickness variable layer, and
the predetermined process includes controlling of a temperature of the thickness variable layer using the heater, and the control unit controls the thickness of the thickness variable layer by controlling of the temperature of the thickness variable layer.

4. The substrate processing apparatus of claim 2, wherein the thickness variable layer expands or shrinks depending on a temperature to thereby change the thickness of the thickness variable layer,
the support unit has therein one or more heaters arranged at positions corresponding to the thickness variable layer, and
the predetermined process includes controlling of a temperature of the thickness variable layer using the heater, and the control unit controls the thickness of the thickness variable layer by controlling of the temperature of the thickness variable layer.

5. The substrate processing apparatus of claim 3, wherein the thickness variable layer shrinks depending on a temperature to thereby reduce the thickness of the thickness variable layer; and
the control unit performs a control of reducing the thickness of the thickness variable layer by controlling the temperature of the thickness variable layer using the heater at predetermined timings.

6. The substrate processing apparatus of claim 4, wherein the thickness variable layer shrinks depending on a temperature to thereby reduce the thickness of the thickness variable layer; and
the control unit performs a control of reducing the thickness of the thickness variable layer by controlling the temperature of the thickness variable layer using the heater at predetermined timings.

7. The substrate processing apparatus of claim 1, further comprising:
a focus ring mounting portion disposed to surround the substrate mounting unit and having an upper surface that serves as a mounting surface on which a focus ring is mounted; and
an additional thickness variable layer disposed between the focus ring and the focus ring mounting portion and having a thickness that changes due to expansion or shrinkage caused by the predetermined process,
wherein the control unit controls the thickness of the additional thickness variable layer by performing the predetermined process.

8. The substrate processing apparatus of claim 2, further comprising:
a focus ring mounting portion disposed to surround the substrate mounting unit and having an upper surface that serves as a mounting surface on which a focus ring is mounted; and
an additional thickness variable layer disposed between the focus ring and the focus ring mounting portion and having a thickness that changes due to expansion or shrinkage caused by the predetermined process,
wherein the control unit controls the thickness of the additional thickness variable layer by performing the predetermined process.

9. The substrate processing apparatus of claim 3, further comprising:
a focus ring mounting portion disposed to surround the substrate mounting unit and having an upper surface that serves as a mounting surface on which a focus ring is mounted, wherein the support unit includes the focus ring mounting portion; and
an additional thickness variable layer disposed between the focus ring and the focus ring mounting portion and having a thickness that changes due to expansion or shrinkage caused by the predetermined process,
wherein the control unit controls the thickness of the additional thickness variable layer by performing the predetermined process.

10. The substrate processing apparatus of claim 5, further comprising:
a focus ring mounting portion disposed to surround the substrate mounting unit and having an upper surface that serves as a mounting surface on which a focus ring is mounted wherein the support unit includes the focus ring mounting portion; and
an additional thickness variable layer disposed between the focus ring and the focus ring mounting portion and having a thickness that changes due to expansion or shrinkage caused by the predetermined process,
wherein the control unit controls the thickness of the additional thickness variable layer by performing the predetermined process.

11. A method of controlling a height of a plasma sheath in a substrate processing apparatus including a substrate mounting unit having an upper surface that serves as a mounting surface on which a target substrate to be processed is mounted; a support unit having therein a flow path for a heat transfer medium and configured to support the substrate mounting unit; and a thickness variable layer disposed between the substrate mounting unit and the support unit, the method comprising:
performing a predetermined process to expand or shrink the thickness variable layer to thereby change a thickness of the thickness variable layer, and
controlling the thickness of the thickness variable layer by performing the predetermined process.
